(19) United States
(12) Patent Application Publication
(10) Pub. No.: US 2017/0070223 A1
(43) Pub. Date: Mar. 9, 2017

(54) DV/DT CONTROL IN MOSFET GATE DRIVE

(71) Applicant: KSR IP Holdings, LLC, Wilmington, DE (US)

(72) Inventor: Eric Hustedt, Halifax (CA)

(21) Appl. No.: 15/180,350

(22) Filed: Jun. 13, 2016

Related U.S. Application Data
(60) Provisional application No. 62/174,229, filed on Jun. 11, 2015.

(51) Int. Cl. H03K 17/284; H03K 5/07

(52) U.S. Cl. CPC H03K 17/284; H03K 5/07

(57) ABSTRACT

An electronic switching circuit having a field effect transistor with a source, a drain, and a gate. A capacitor and resistor are connected in series between a gate and the source of the field effect transistor. The input signal to the circuit is connected at the junction between the capacitor and resistor.

### CROSS-REFERENCE TO RELATED APPLICATIONS

This application claims priority of U.S. Provisional Application No. 62/174,229 filed Jun. 11, 2015, the contents of which are incorporated herein by reference.

### BACKGROUND OF THE INVENTION

I. Field of the Invention

The present invention relates to a dV/dt control for a MOSFET gate drive.

II. Description of Related Art

MOSFETs are frequently used for low voltage, high current applications for a number of reasons. In particular, MOSFETs exhibit a high input impedance and the losses from the MOSFET are dominated by the “on” state resistance which can be very small thus minimizing the losses. MOSFETs also exhibit high switching speed.

MOSFETs are three terminal devices, namely a gate terminal, a drain terminal, and a source terminal. However, in addition to these three terminals, all MOSFETs exhibit internal capacitances. These capacitances include the Cgd or Miller capacitance between the gate and drain, the Cgs capacitance between the gate and the source, as well as the Cds capacitance between the drain and source. MOSFETs also exhibit some internal inductance, but the amount of inductance is so trivial that it only affects the operation of the MOSFET at extremely high frequencies. As such, the internal inductance for the MOSFET may be safely disregarded.

The capacitance between the gate and source Cgs is typically in the range of one to tens of nanofarads and its main impact from the operation of the MOSFET is the energy required to drive the MOSFET. In particular, a bucket of charge must be pushed into and then removed from the gate capacitance again for one on/off cycle, i.e. the switching frequency of the MOSFET. Even if the drain to source voltage is zero, the switching energy must still be supplied and subsequently removed.

The gate to drain capacitance, Cgd, often called the Miller capacitance, affects the operation of the MOSFET in an entirely different fashion. In particular, when the MOSFET is turned on with zero voltage between the drain and source, e.g. in synchronous rectification, then the Miller capacitance is simply in parallel with Cgs and this capacitance has no dynamic effect beyond its RC time constant. This occurs since Vgd does not change due to the FET switching. However, when a MOSFET is turned on with some amount of Vds, i.e. the typical situation, then the Miller capacitance must be discharged (or charged) by more than simply the gate voltage.

If a MOSFET gate is left unconnected, i.e. floating, then the Miller and gate capacitors form a capacitive voltage divider between the drain, gate, and source. As such, any change in the drain-source voltage is applied through the corresponding capacitive divider ratio to the gate.

Since there is no resistance to bleed the charge away within the device, the rate of change of Vds does not matter. The rate of change of Vds does, however, affect the peak current flowing between the drain and source through these two capacitors. Thus, the faster the voltage change, the larger the current pulse is obtained.

For example, in one MOSFET, part number AUIRFS3006, the Miller capacitance is approximately 0.8 nanofarads while the Miller capacitance plus Cgs is approximately 9.2 nanofarads. Consequently, the drain to source capacitance via the gate path equals approximately 0.74 nanofarads and the capacitive divider ratio is approximately 10.

Typically a gate resistor is selected to control the FET switching. Specifically, to slow down a FET, the gate resistor is increased until the required dV/dt is reached. This not only slows down the device switching transition but also dramatically delays the time when the gate driver is turned on and the FET gate reaches its threshold.

Increasing the gate resistor also delays the turn off time for the FET. Consequently, simply increasing the gate resistance to slow down the switching edges for the turn on of the FET negatively affects the switching off time for the FET.

Changing the gate resistor does ultimately change the switching time for the FET, but is very dependent upon several conditions. First, for a resistive load or a mildly inductive load, the turn on time for the FET may be slowed and controlled. In a motor drive, the FET experiences a number of different conditions during the electrical cycle of the motor. Consequently, if you slow down the FET to an extent that the reverse recovery is controlled, it may result in a shoot through for the FET. This may result in dead times for the FET.

This occurs because the gate resistor controls the charging of the gate and, during the plateau, it is basically acting like a current source since the gate voltage is constant. The rate at which the gate is charged is then determined by this current source. Consequently, the problem is that the charge rate (coulombs per second) required is different depending upon what the FET is doing for a given dV/dt. Consequently, a fixed gate resistor is a fixed charge per second device, at least during the plateau period, which may not result in the same final dV/dt depending upon the conditions surrounding the FET.

Furthermore, the gate resistor limits the amount of charge available to the device so that the dV/dt may not be controllable under all conditions.

### SUMMARY OF THE PRESENT INVENTION

The present invention provides a dV/dt control for a MOSFET gate drive which overcomes the above mentioned disadvantages by reducing the switching speed of the MOSFET.

In brief, the present invention comprises a capacitor and a resistor connected in series between the drain and gate inputs of the MOSFET. The input signal is then connected between the junction of the capacitor and the resistor and the source for the MOSFET.

The value of the capacitor is then selected to effectively reduce the switching time for the MOSFET and effectively reduces the slew rate for the MOSFET.

### BRIEF DESCRIPTION OF THE DRAWING

A better understanding of the present invention will be had upon reference to the following detailed description when read in conjunction with the accompanying drawing, wherein like reference characters refer to like parts, and in which:

FIG. 1 is a schematic view illustrating the present invention.

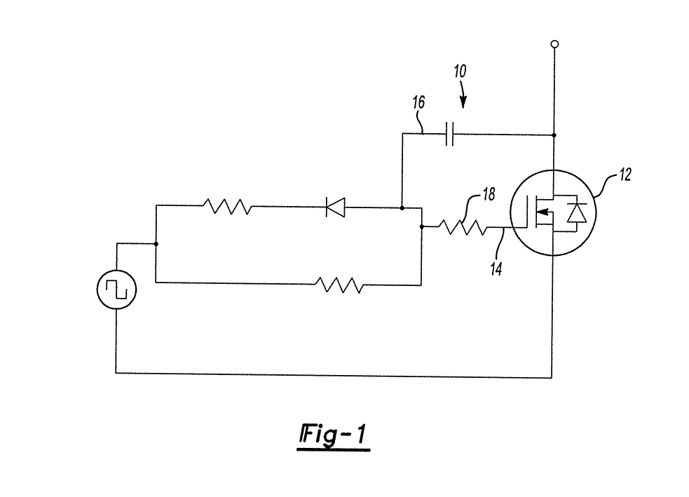

### DETAILED DESCRIPTION OF PREFERRED EMBODIMENTS OF THE PRESENT INVENTION

Again using the MOSFET AUIRFS3006 as an example, the 3006 device has a large gate capacitance, small Miller capacitance, and therefore inherently fast switching speeds. Consequently, to reduce the dV/dt by increasing the gate resistor results in large increases in timing delays due to the large Cgs but with a smaller impact on the rise and fall times during switching.

In order to more actively control the dV/dt, the gate driver plus the MOSFET may be viewed as an inverting Class A linear amplifier with a large voltage gain that is driven into saturation. At saturation it provides a different way to view things like the effect of the Miller capacitance as well as the control of switching speeds.

As shown in the drawing, a high frequency negative feedback 10 is used to control the switching speed of a MOSFET 12 by reducing the gain of the amplifier at the high frequency.

As shown in the drawing, the MOSFET 12 and its gate drive 14 essentially form a common source inverting amplifier. Therefore, since phase inversion occurs between the gate and drain, simply feeding a portion of the drain voltage back into the gate will produce the negative feedback. Resistors could be used to provide this feedback if a lower closed loop gain was desired, but, as shown in the drawing, a capacitor 16 coupled between the FET drain and FET gate resistor 18 can be used for the negative feedback and provide a limited response at high frequencies. That, in turn, accomplishes a reduction in the dV/dt as desired.

The key difference is that the capacitor controls the amount of charge applied to the gate from the gate drive dependent upon how fast the FET is switching, rather than applying a fixed amount of charge. Consequently, by adding negative HF feedback to the FET drivers to control high dV/dt edges does control the FET slew rate without significantly increasing switch timing. As such, the rise and fall time for the FET during switching may be changed, but the switching delay remains largely the same.

Other types of switching devices which have a gate structure, such as IGBTs, may be used instead of the MOSFETs.

In practice, the value of the capacitor 16 is selected so that the switching speed of the MOSFET meets or slightly exceeds the fastest switching speeds for the circuit application of the MOSFET. However, by utilizing the capacitor to limit the switching speed for the MOSFET, the previously known circuit ringing and other adverse consequences of uncontrolled switching speeds for the MOSFET are avoided.

Having described my invention, many modifications thereto will become apparent to those skilled in the art to which it pertains without deviation from the spirit of the invention as defined by the scope of the appended claims.

I claim:

1. An electronic switching circuit comprising:
a field effect transistor having a source, a drain and a gate,
a capacitor and a resistor connected in series between said gate and said source of said field effect transistor,
wherein said circuit receives a signal between said drain and a junction between said capacitor and said resistor.

2. The circuit as defined in claim 1 wherein said transistor comprises a field effect transistor.

3. The circuit as defined in claim 1 wherein the value of said capacitor is selected so that the switching speed of said field effect transistor is reduced.
